(19) United States
(12) Patent Application Publication
(10) Pub. No.: US 2005/0084118 A1
(43) Pub. Date: Apr. 21, 2005

(54) Circuit arrangement for an electric appliance

(76) Inventors: Kurt Schaupert, Hofheim (DE); Thomas Zenker, Nieder Olm (DE); Gerold Ohl, Sulzheim (DE)

Correspondence Address: Pauley Petersen & Erickson;Suite 365, 2800 W. Higgins Road, Hoffman Estates, IL, 60195, US

(21) Appl. No.: 10/927,950

(22) Filed: Aug. 27, 2004

(30) Foreign Application Priority Data
Aug. 27, 2003 (DE) 103 39 410.9

(51) Int. Cl. H04R 3/00; H03G 3/20

(52) U.S. Cl. 381/110; 381/111

(57) ABSTRACT

A circuit arrangement for an electric appliance, having a control device and a power supply connected with an electric current supply connector for supplying functional units to be controlled of the electric appliance. A switching device for the separation of the power supply from the electric current supply connector at the primary side is provided at the electric current supply connector, which has a comparator, which can be activated by an electrical activation signal (A). It is used, for example, in electronically controlled household appliances.

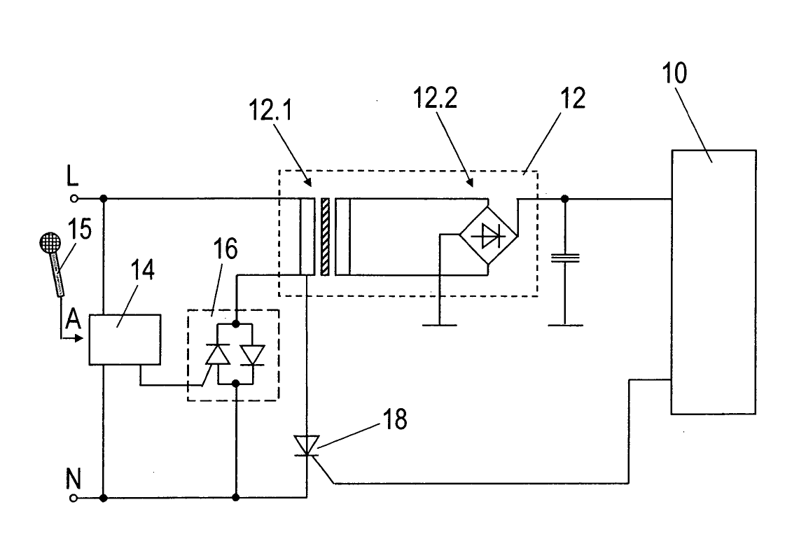

### BACKGROUND OF THE INVENTION

1. Field of the Invention

This invention relates to a circuit arrangement for an electric appliance, having a control device and a power supply connected with an electric current supply connector for supplying functional units to be controlled, of the electric appliance. A switching device for the separation of the power supply from the electric current supply connector at the primary side is provided at the electric current supply connector.

2. Discussion of Related Art

It is known from the prior art to equip electric appliances, for example in the household, with electronic controls. Electronic touch controls are used for cooking surfaces, ovens, dishwashers, washing machines and similar household appliances. It is disadvantageous to keep the keys ready to be able to react to input. The appliances use a so-called static current for this purpose. This static current is defined by the consumption of the implemented electronic circuits and the losses of the power transformer. In this case the power consumption typically lies in the range of 1 W up to 1.5 W. Although such a power consumption is relatively low in one electronic circuit, with the large number of devices typically used today the overall power consumption can be quite considerable.

It is known to have electronic controls without static current. In this case a central mechanical switch can be provided, for example. However, one disadvantage is that the operating concept of touch controls is thus disrupted. For changing its status between ON and OFF, the mechanical switch requires a travel of the switch lever. Thus the operating surface needs an opening which increases the manufacturing costs of such an operating surface, cleaning is more difficult, and it is necessary to accept restrictions in the design.

A cooking surface is known from German Patent Reference DE 199 23 148 A1, wherein the energy supply can be switched on via a reed contact. However, when using a reed contact there is a disadvantage because a magnet is required for activation, which under certain circumstances might become lost.

### SUMMARY OF THE INVENTION

It is one object of this invention to provide a circuit arrangement for an electric appliance which makes it possible to simply operate the electric appliance from a standby state without a considerable static current and, upon switch-off, to return it into a standby state, without a considerable static current. Also, the circuit arrangement in accordance with this invention is intended to make unnecessary mechanical switches requiring an opening in the operating surface and thus minimize the production costs of the operating surface and simplify cleaning.

The above object of this invention is accomplished with a circuit arrangement as described in this specification and in the claims.

A switch for the separation of the power supply from the electric current connector at the primary side has a comparator which can be activated by an electrical activating signal. The comparator has a particularly low static current and can be attached underneath closed metal or glass surfaces or similar surfaces.

The comparator can be activated by an output signal of a signal generation device. The signal generation device can convert, for example, optical or acoustic signals to the required electric activation signal.

In accordance with one embodiment, the signal generation device has a microphone, or a loudspeaker acting as a microphone, so that the comparator can be activated by the generation of a noise, for example a knocking noise. The microphone can here also be installed underneath closed metal or glass surfaces or similar surfaces, since it is possible to assure the required sound propagation through such surfaces.

In accordance with a further embodiment, the comparator is connected with a power semiconductor circuit which, when the comparator is activated, connects the control device for activating it with the electrical current supply connector. Thus the control device receives the current required for the activation of further functions in a short time.

In accordance with a preferred embodiment, the power semiconductor circuit has at least one triac (triode AC semiconductor switch). The activated comparator switches the triac, which connects the control device with the electrical current supply connector via the power supply.

For maintaining the electrical current supply of the electric appliance during operation, the control device can be advantageously connected with a holding circuit which can be activated by the control device. Thus the electrical power supply is maintained.

In accordance with one embodiment, the holding circuit has at least one thyristor. The holding circuit can also have an electro-mechanical relay or a reed relay.

For separating the control device from the electric power supply connector when the electric appliance is switched off, the control device is connected with an appropriate semiconductor circuit. The control device can then deactivate the holding circuit for separation from the electrical power supply connector and for switching off the electrical appliance.

### BRIEF DESCRIPTION OF THE DRAWING

This invention is described in greater detail in view of a preferred embodiment wherein the figure represents a schematic circuit diagram of a circuit arrangement for an electric appliance, such as used in a household appliance.

### DESCRIPTION OF PREFERRED EMBODIMENTS

The circuit arrangement has an electrical power supply connector with two individual connections L and N. A comparator is provided on the circuit side between the electrical power supply connections L and N.

The voltage supply connector L is connected with a connector on the primary side of a transformer 12.1. The second connector on the primary side of the transformer 12.1 is interconnected via a triac 16 with the electrical power supply connector N, and also via a triac 18 with the electrical power supply connector N. A control connection of the triac 16 is interconnected with the comparator 14. The control connection of the triac 16 is connected with a control device 10. The two connections on the secondary side of the transformer 12.1 are interconnected with a rectifier bridge 12.2, which on its output side is connected with the control device 10. Together, the transformer 12.1 and the rectifier bridge 12.2 form the power supply 12.

The electronic control device 10 is activated via the comparator 14. The comparator 14 uses a few μW, at most a few mW, so that the resultant static current is extremely low.

The comparator 14 is triggered by an activation signal A. The activation signal A is generated by a microphone arrangement 15. The associated microphone, or a loudspeaker acting as a microphone, can be arranged, for example, underneath the closed ceramic cooking surface, not shown, or similar surfaces, because the required sound propagation through such surfaces is assured. For example, an acoustic signal is generated by the user knocking on the cooktop of a cooking surface, and is converted into an electrical signal in the microphone arrangement 15. This electrical signal forms the activation signal A for the comparator 14, which triggers the triac 16 that in turn switches the power supply 12 on, so that the device is in the standby mode.

In the standby mode, the control device 10 is switched off after a preset time, for example 15 sec, if no active operation by the user is performed, for example the turning on of a cooking location.

Alternatively, the circuit arrangement can also be activated by a light pulse. Thus it is possible, for example, to employ a light-sensitive signal generating element arranged underneath the glass cooking surface, which switches on the actual electronic control via the comparator 14 and the triac 16.

An amplifier circuit is employed as the comparator 14, which is realized, for example, by an amplifier of the type LTC 1540 of the Linear Technology company. This comparator can be operated in a voltage range between 2 V and 11 V and maximally requires 0.6 μA of operating current. Its output can drive logical circuits or electric and electronic relays.

For switching the electric appliance on, a knocking noise is generated, for example by placing the pot on the cooking surface, not shown, which is received by the microphone arrangement 15 arranged underneath the cooking location. The microphone arrangement 15 generates an activation signal A, which activates the comparator 14 that switches on the triac 16, which briefly supplies current to the control device 10 via the power supply 12. Based on this brief current supply, the control device 10 switches the thyristor 18 on, so that the power supply is maintained. Thus the thyristor 18 is a part of a holding circuit.

If the electric appliance is to be turned off, the control device 10 cancels the signal present at the thyristor 18, so that the electric power supply is practically completely switched off. It is also possible to use an electro-mechanical relay or a reed relay in place of the thyristor 18.

In a further exemplary embodiment, not shown, the comparator 14 triggers a micro-controller, which is in the standby mode and therefore also uses very little power. The micro-controller can then evaluate various noise patterns and start only in case of defined predetermined patterns.

It is possible with the circuit arrangement in accordance with this invention to bring an electric appliance into a standby mode, in which only a very low static current flows, without the use of a mechanical switch.

German Patent Reference 103 39 410.9, the priority document corresponding to this invention, and its teachings are incorporated, by reference, into this specification.

1. A circuit arrangement for an electric appliance, having a control device (10) and a power supply (12) connected with an electric current supply connector (L, N) for supplying controllable units of the electric appliance, wherein a switching device (14) for a separation of the power supply (12) from the electric current supply connector (L, N) at a primary side is provided at the electric current supply connector (L, N), the circuit arrangement comprising:
the switching device (14) having a comparator activated by an electrical activation signal (A).

2. The circuit arrangement in accordance with claim 1, wherein the activation signal (A) is an output signal of a signal generation device (15).

3. The circuit arrangement in accordance with claim 2, wherein the signal generation device (15) converts at least one of an optical signal, an acoustic signal and an other signal into the electrical activation signal (A).

4. The circuit arrangement in accordance with claim 3, wherein the signal generation device (15) has one of a microphone and a loudspeaker.

5. The circuit arrangement in accordance with claim 4, wherein a comparator is connected with a power semiconductor circuit (16) so that when activated the comparator connects the control device (10) with the electrical current supply connector (L, N) for activation.

6. The circuit arrangement in accordance with claim 5, wherein the power semiconductor circuit (16) has at least one triode AC semiconductor switch.

7. The circuit arrangement in accordance with claim 6, wherein the activated power semiconductor circuit (16) connects the control device (10) with the electrical current supply connector (L, N) via the power supply (12).

8. The circuit arrangement in accordance with claim 7, wherein for maintaining an electrical current supply of the electric appliance during operation the control device (10) is connected with a holding circuit (18) activated by the control device (10).

9. The circuit arrangement in accordance with claim 8, wherein the holding circuit has at least one thyristor (18).

10. The circuit arrangement in accordance with claim 9, wherein the holding circuit has at least one of an electro-mechanical relay and a reed relay.

11. The circuit arrangement in accordance with claim 10, wherein the control device (10) is connected with a semiconductor circuit for separation from the electrical power supply connector (L, N).

12. The circuit arrangement in accordance with claim 11, wherein the control device (10) deactivates a holding circuit for separation from the electrical power supply connector (L, N) and for switching off the electric appliance.

13. The circuit arrangement in accordance with claim 2, wherein the signal generation device (15) has one of a microphone and a loudspeaker.

14. The circuit arrangement in accordance with claim 1, wherein a comparator is connected with a power semiconductor circuit (16) so that when activated the comparator connects the control device (10) with the electrical current supply connector (L, N) for activation.

15. The circuit arrangement in accordance with claim 14, wherein the power semiconductor circuit (16) has at least one triode AC semiconductor switch.

16. The circuit arrangement in accordance with claim 5, wherein the activated power semiconductor circuit (16) connects the control device (10) with the electrical current supply connector (L, N) via the power supply (12).

17. The circuit arrangement in accordance with claim 1, wherein for maintaining an electrical current supply of the electric appliance during operation the control device (10) is connected with a holding circuit (18) activated by the control device (10).

18. The circuit arrangement in accordance with claim 17, wherein the holding circuit has at least one thyristor (18).

19. The circuit arrangement in accordance with claim 8, wherein the holding circuit has at least one of an electro-mechanical relay and a reed relay.

20. The circuit arrangement in accordance with claim 1, wherein the control device (10) is connected with a semiconductor circuit for separation from the electrical power supply connector (L, N).

21. The circuit arrangement in accordance with claim 8, wherein the control device (10) deactivates a holding circuit for separation from the electrical power supply connector (L, N) and for switching off the electric appliance.
